(19) United States
(12) Patent Application Publication
(10) Pub. No.: US 2009/0095927 A1
(43) Pub. Date: Apr. 16, 2009

(54) THERMALLY ACTUATED VALVES, PHOTOVOLTAIC CELLS AND ARRAYS COMPRISING SAME, AND METHODS FOR PRODUCING SAME

(76) Inventors: Matthew McCarthy, Silver Spring, NY (US); Vijay Modi, New York, NY (US); Luc Frechette, Sherbrooke (CA); Nicholas Tiliakos, Huntington Station, NY (US)

Correspondence Address: WilmerHale/Columbia University, 399 PARK AVENUE, NEW YORK, NY, 10022, US

(21) Appl. No.: 12/092,501

(22) PCT Filed: Nov. 6, 2006
(86) PCT No.: PCT/US2006/043165

§ 371 Date: Nov. 25, 2008

Related U.S. Application Data
(60) Provisional application No. 60/733,980, filed on Nov. 4, 2005.
(60) Provisional application No. 60/802,380, filed on May 22, 2006.
(60) Provisional application No. 60/817,673, filed on Jun. 30, 2006.
(60) Provisional application No. 60/830,500, filed on Jul. 13, 2006.

(51) Int. Cl. F16K 31/64; B81B 3/00; B81C 1/00

(52) U.S. Cl. 251/11; 136/259; 438/54

(57) ABSTRACT

Thermally actuated valves, photovoltaic cells and arrays comprising same, and methods for producing same are disclosed. In some embodiments, thermally actuated valves are provided, comprising: a first material defining at least one opening; and a beam attached to the first material so as to at least partially cover the at least one opening, wherein the first material and the beam comprise different thermal expansion properties, such that, when a temperature is applied to at least one of the first material and the beam, the beam buckles so as to at least partially uncover the at least one opening. In some embodiments, photovoltaic cells and arrays comprising thermally actuated valves, and methods for producing thermally actuated valves are provided.

### CROSS-REFERENCE TO RELATED APPLICATION

This application claims the benefit of U.S. Provisional Patent Application No. 60/733,980, filed on Nov. 4, 2005, U.S. Provisional Patent Application No. 60/802,380, filed on May 22, 2006, U.S. Provisional Patent Application No. 60/817,673, filed on Jun. 30, 2006, and U.S. Provisional Patent Application No. 60/830,500, filed on Jul. 13, 2006, all of which are hereby incorporated by reference herein in their entireties.

### TECHNOLOGY AREA

The disclosed subject matter relates to thermally actuated valves, photovoltaic cells and arrays comprising same, and methods for producing same.

### BACKGROUND

The advent of micro-electro-mechanical systems (MEMS) has enabled the development of very small electromechanical systems. That is, MEMS structures are typically no larger than a few hundred microns. To put that into perspective, a fully functioning MEMS device (e.g., a motor with moving parts) can be smaller than a human hair. Because of the very small size of MEMS, designing MEMS challenges typical engineering in many ways. For example, because MEMS are so small they can exhibit a large surface-area-to-volume ratio. Because of this large surface-area-to-volume ratio, surface effects such as electrostatics, thermal responses, and wetting can significantly affect the MEMS volume.

Volume changes due to heat transfer have been well studied. For example, it is well known that during heat transfer, energy that is stored in the intermolecular bonds between atoms changes. As stored energy increases, typically so does the length of the molecular bond. Because of this phenomenon, solids typically expand in response to heating and contract in response to cooling. Further, most materials exhibit varying amounts of thermal expansion. For example, metals tend to exhibit greater thermal expansion than ceramics. In the design of mechanical systems, thermal expansion can play a critical role. For example, when designing supersonic jets, engineers must consider the expansion of the jets' body due to frictional heat.

Some valves utilize thermal properties to operate in temperature sensitive systems. For example, a car thermostat uses the thermal expansion of components in the thermostat to open a valve allowing coolant to flow through the engine. Accordingly, many benefits can be achieved by designing mechanical devices (e.g., valves), which utilize the thermal properties of various materials in the device.

### SUMMARY

Thermally actuated valves, photovoltaic cells and arrays comprising same, and methods for producing same are disclosed. In some embodiments, thermally actuated valves are provided, comprising: a first material defining at least one opening; and a beam attached to the first material so as to at least partially cover the at least one opening, wherein the first material and the beam comprise different thermal expansion properties, such that, when a temperature is applied to at least one of the first material and the beam, the beam buckles so as to at least partially uncover the at least one opening.

In some embodiments, arrays of valves are provided, comprising: a first material defining at least two openings; a first beam attached to the first material so as to at least partially cover one of the at least two openings; and a second beam attached to the first material so as to at least partially cover another of the at least two openings, wherein the first material and each of the first beam and the second beam comprise different thermal expansion properties, such that, when a temperature is applied to at least one of the first material and the first beam, the first beam buckles so as to at least partially uncover the one of the at least two openings.

In some embodiments, photovoltaic cells are provided, comprising: a first material defining at least one opening; and a beam attached to the first material so as to at least partially cover the at least one opening, wherein the first material and the beam comprise different thermal expansion properties, such that, when a temperature is applied to at least one of the first material and the beam, the beam buckles so as to at least partially uncover the at least one opening.

In some embodiments, methods for producing thermally actuated valves are provided, the methods comprising: producing a first material defining at least one opening; producing a beam having different thermal expansion properties from the first material on the first material so that the beam at least partially covers the at least one opening, wherein when a temperature change is applied to at least one of the first material and the beam, the beam buckles at least partially uncovering the at least one opening.

### DESCRIPTION OF DRAWINGS

The disclosed subject matter will be apparent upon consideration of the following detailed description, taken in conjunction with accompanying drawings, in which:

FIG. 1 is a drawing illustrating a beam attached to a substrate producing a thermally actuated micro-valve in accordance with some embodiments of the disclosed subject matter;

FIG. 2 is a drawing displaying a thermally actuated micro-valve in accordance with some embodiments of the disclosed subject matter;

FIGS. 3A and 3B are drawings illustrating a method for producing a thermally actuated micro-valve in accordance with some embodiments of the disclosed subject matter;

FIG. 4 is a drawing illustrating a beam that can be produced for use in a thermally actuated micro-valve in accordance with some embodiments of the disclosed subject matter;

FIG. 5 is a drawing illustrating a thermally actuated micro-valve in conjunction with a heat exchanger in accordance with some embodiments of the disclosed subject matter;

FIG. 6 is a drawing illustrating an array of thermally actuated micro-valves in accordance with some embodiments of the disclosed subject matter;

FIG. 7 is a drawing illustrating a thermally actuated micro-valve constructed into a heat exchanger in accordance with some embodiments of the disclosed subject matter;

FIGS. 8 and 9 are drawings illustrating a thermally actuated micro-valve in conjunction with a photo-voltaic cell and an aeronautical vehicle in accordance with some embodiments of the disclosed subject matter; and

FIGS. 10-18 are drawings and graphs used to illustrate mathematically a relationship that can be used to produce thermally actuated micro-valves in accordance with some embodiments of the disclosed subject matter.

### DETAILED DESCRIPTION

Thermally actuated valves, photovoltaic cells and arrays comprising same, and methods for producing same are disclosed.

In some embodiments, thermal expansion and MEMS-sized components can be combined to produce a thermally actuated micro-valve. For example, in some instances, a valve can be formed from a MEMS-sized beam attached to a substrate with an opening in it and using a material for the MEMS-sized beam that exhibits a larger amount of thermal expansion than the substrate. Such a selection of materials attached to each other can cause buckling (i.e., bending of the beam due to a force on it) of the MEMS-sized beam when the beam and the substrate are heated, resulting in the valve being opened. Thus, in use, for example, if the substrate has coolant on one side of it, when enough heat is applied, the valve will open and then the coolant will flow through the hole. When lower amounts of heat are applied, the hole is covered by the MEMS-sized beam and the coolant is inhibited from flowing through the hole. After the valve is opened, when the beam returns to a lower temperature, it can return to its original pre-buckling position and cover the hole.

In some embodiments, the temperature at which the beam buckles can be tailored to a specific temperature based on its geometry and material properties. This can be done over a wide range of temperatures (e.g., 65 C to 150 C). For example, the beam can be eccentric and this eccentricity can make the beam slightly asymmetric, which in turn can amplify deflections associated with buckling. For example, the eccentricity in the beam produces larger deflections at a given temperature rise or amount of thermal expansion.

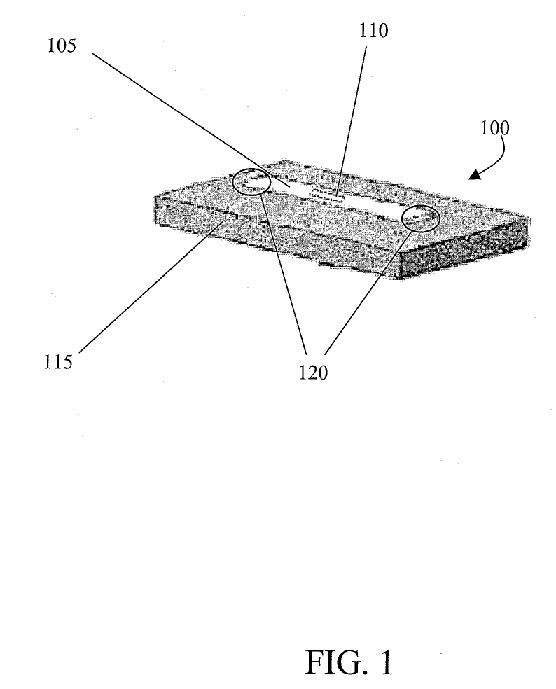

Referring to FIG. 1, in some embodiments, a thermally actuated valve 100 includes a first material 115 (e.g., a silicon substrate) including an opening 110 (e.g., a drilled hole) and a beam 105 (e.g., an electro-plated nickel beam) that is attached to first material 115. In some embodiments, beam 105 at least partially covers opening 110. For example, at least partially covering opening 110 can lessen the flow of material (e.g., coolant) through opening 110. In some embodiments, beam 105 can be attached to first material 115 at the two ends of beam 105 (e.g., attaching regions 120).

In some embodiments, opening 110 can be produced by removing at least some material from first material 115. For example, drilling a hole in first material 115 can produce opening 110. Drilling a hole may produce, for example, a circular shape in the surface of first material 115 for opening 110. In some instances, the shape on the surface of first material 115 for opening 110 is at least one of circular, square, rectangular, or any other shape deemed suitable. For example, in some instances, the shape on the surface of first material 115 for opening 110 is designed to increase or decrease flow (e.g., coolant flow, etc.) through opening 110. In some instances, the shape on the surface of first material 115 can increase the frictional forces on the coolant thereby decreasing flow through opening 110. In some instances, opening 110 is produced by, for example, drilling, laser removal, chemical etching, or any other means deemed suitable. In some instances, first material 115 can be at least one of molded (e.g., poured in as a liquid and allowed to cure, etc.), deposited (e.g., spin cast, solution cast, thermally evaporated, electrostatically spun, etc.), and patterned (e.g., using photolithography, soft lithography, printing, etc.) around an object (e.g., a pin, cone, block, chemical substrate, etc.). Later, that object can be removed (e.g., thermal evaporation, peeled away, chemically removed, etc.) producing opening 110. In some instances, more than one opening 110 can be created in first material 115. For example, a plurality of openings may be located in first material 115 creating an array of openings. An array of openings can, for example, be produced to cause coolant flow through first material 115.

In some embodiments, first material 115 can include a substantially homogenous material. For example, first material 115 can include a monolithic silicon substrate. In other instances, first material 115 can include a non-homogenous material (e.g., a mixture, a blend, etc.). For example, first material 115 can include a mixture of a metal (e.g., nickel, molybdenum, cobalt, etc.) and a ceramic. As another example, first material 115 can include a mixture of nickel-titanium alloy (e.g., to include in first material 115 some amount of shape memory) and a ceramic (e.g., to include in first material 115 some lessened thermal expansion). In some instances, first material can include a mixture of silicon and carbon (e.g., silicon carbide) for at least increasing functionality at higher temperatures. In some instances, first material 115 can be substantially rectangular in shape. In other instances, first material 115 can be square, curved, or any other shape deemed suitable.

In some embodiments, first material 115 can include a material that exhibits different amounts (e.g., substantially lesser amounts) of thermal expansion than beam 105. For example, first material 115 can be a metalloid (e.g., a silicon substrate), a metal (e.g., tungsten), a ceramic, a glass, or any other material deemed suitable. First material 115 can include any material that exhibits substantially less thermal expansion than the thermal expansion exhibited by beam 105.

In some embodiments, beam 105 can include a material that exhibits different amounts (e.g., substantially higher amounts) of thermal expansion than first material 115. For example, beam 105 can include a metal (e.g., electroplated nickel, zinc, lead, aluminum, tin, etc.), alloys (e.g., nickel-titanium, aluminum alloy, tin alloy, etc.), or any other material deemed suitable. In some embodiments, first material 115 and beam 105 can be two dissimilar materials. In some embodiments, beam 105 can be substantially rectangular. For example, beam 105 can include a thickness of about 10-100 microns, a width of about 50-500 microns, and a length of about 500-5000 microns.

In some embodiments, beam 105 can be a membrane (e.g., a thin flat surface) or a plate. Similar to a rectangular beam 105, a membrane or a plate shaped beam can be attached on at least two sides and can exhibit thermally induced compressive stresses that can lead to thermal buckling. In some embodiments, beam 105 can be a clamped structure that can buckle in many different ways. For example, a flat square plate beam clamped on all four edges that can buckle at elevated temperatures. This flat square plate beam can exhibit a dome shape (e.g., the center of the flat square plate beam can buckle away from first material 115) form of buckling when heated. This dome shaped form of buckling can increase flow through the gap underneath it. In other instances, beam 105 can be disc shaped, substantially flat, or any other shape deemed suitable. For example, beam 105 can be substantially disc shaped for at least partially covering a round opening 110.

In some embodiment, beam 105 can be permanently attached to first material 115 through electrodeposition. For example, beam 105 can be fabricated directly onto material 115. In some embodiments, beam 105 can be attached to first material 115 by welding, gluing, casting, or by any other means deemed suitable. In some instances, beam 105 can be permanently attached to first material 115 to ensure buckling in at least one direction. For example, beam 105 can be attached to first material 115 at an angle (e.g., the area in attaching region 120 nearer to opening 110 can exhibit a slightly larger gap between the surface of first material 115 and beam 105 than the area in attaching region 120 further from opening 110). That angle, for example, can cause beam 105 to buckle away from opening 110 allowing coolant to flow through opening 110. In some instances, beam 105 can be attached to first material 115 on the external surface of first material 115 (e.g., as shown in FIG. 1).

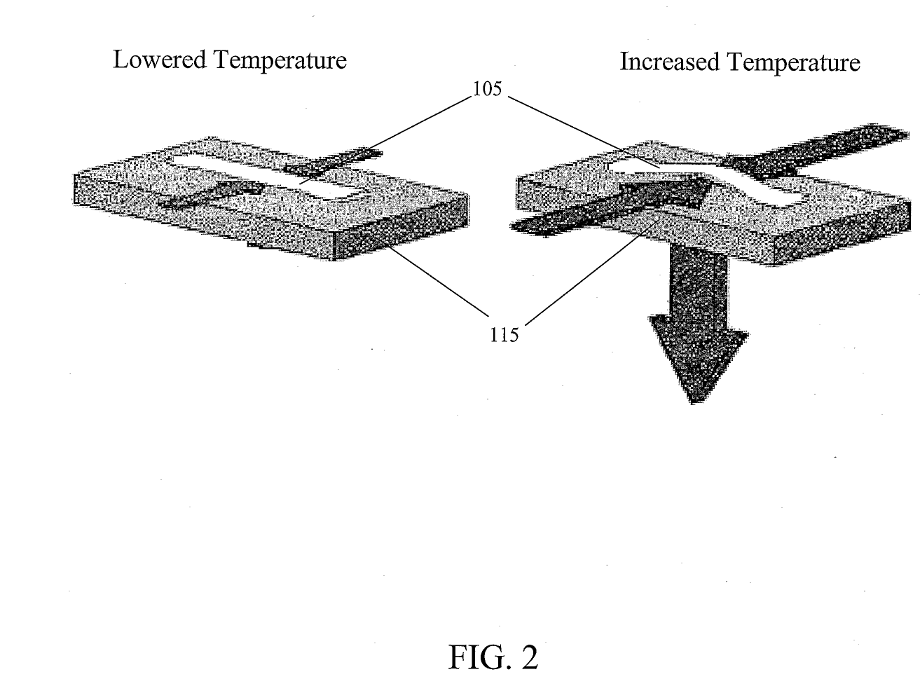

In some embodiments, beam 105 can buckle in a direction substantially within the same plane as first material 115. For example, unlike FIG. 2, where beam 105 buckles away from first material 115, beam 105 can offset to the side (e.g., shuttle) remaining substantially close to first material 115. In some embodiments, beam 105 can buckle away from material 115 and at some angle to opening 110. For example, beam 105 can buckle away from material 115 and offset from the pre-buckled position of beam 105. It will be apparent that beam 105 can be configured to buckle in any suitable direction or directions to at least partially allow flow through opening 110.

In some embodiments, at ambient temperature beam 105 attached to first material 115 is pre-stressed (e.g., exhibits compressive residual stress, exhibits tensile residual stress, etc.). In some embodiments, beam 105 can be pre-stressed by varying the deposition temperature, current density, electroplating bath pH, and chemical composition. For example, a tensile residual stress can increase the temperature needed to induce buckling. That is, beam 105 will need to heat up some amount to overcome the pre-existing tension. A compressive residual stress can lower the temperature needed to induce buckling.

In some embodiments, beam 105 buckles so that the mass flow rate through the micro-valve increases nonlinearly once a given temperature is reached. For example, beam 105 can allow minimal or zero mass flow rates through first material 115 until a given temperature is reached. When that given temperature is reached, beam 105 can buckle and allow substantially larger mass flow rates through first material 115. This buckling causes a nonlinear increase in mass flow rate through first material 115 as the temperature rises at the given temperature. The given temperature for buckling can be predetermined, allowing controlled mass flow rates at a specific temperature.

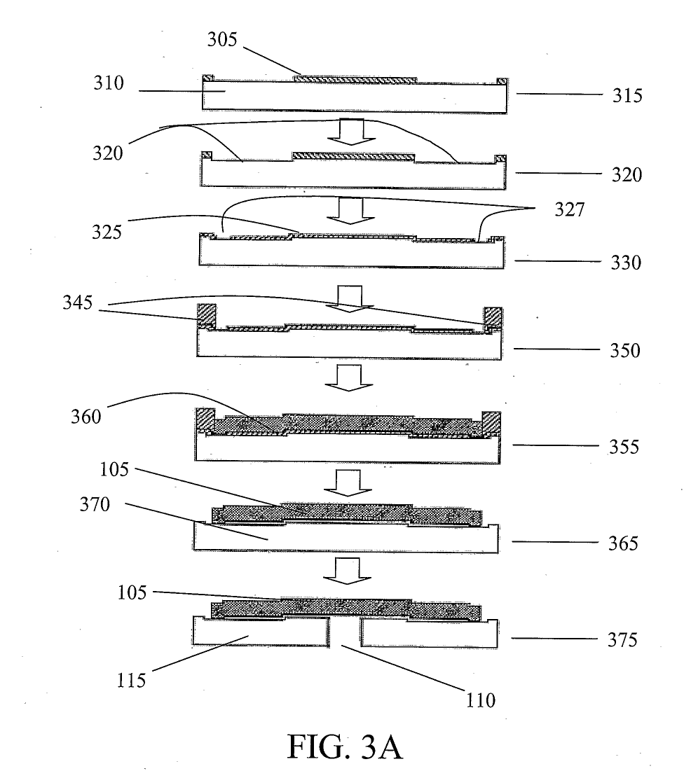

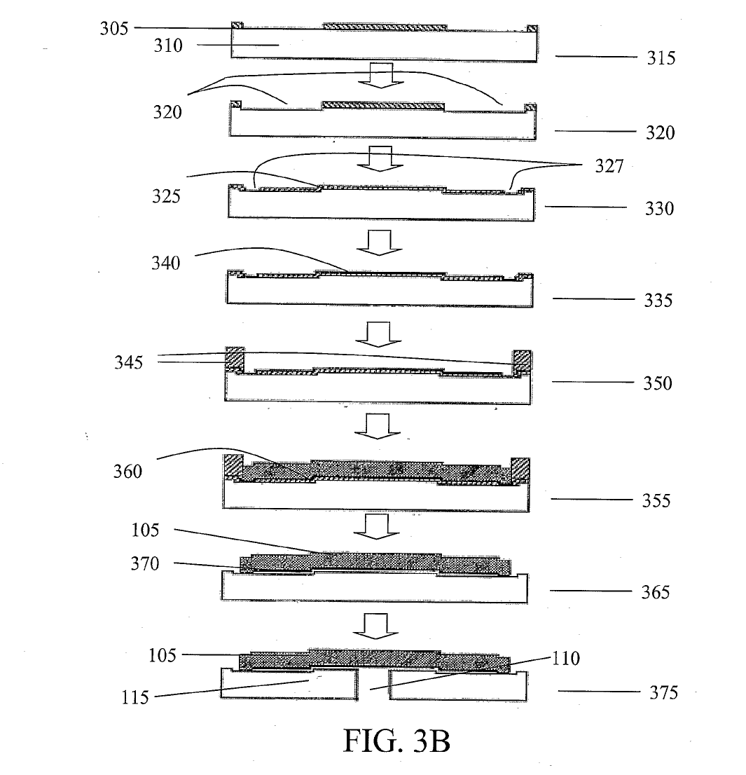

Referring to FIG. 3A, in some embodiments, beam 105 can be constructed to cause buckling in at least one direction. For example, beam 105 can be constructed to cause buckling away from opening 110 by constructing beam 105 with an eccentricity. A first resistant material 305 can be deposited (e.g., spin cast, solution cast, thermally evaporated, electrostatically spun, etc.) and patterned (e.g., using photolithography, soft lithography, printing, etc.) on a substrate 310 (e.g., silicon wafer, glass surface, polished metal, etc.) at 315. At 320, at least some substrate 310 (e.g., substrate surface not covered by first resistant material 305) can be removed. Substrate 310 can be removed, for example, using wet etching with etchants (e.g., NaOH, HNO3, HCl, etc.) or dry etching using a suitable gas (e.g., CF₄O₂). First resistant material 305 can be stripped away (e.g., thermal evaporated, peeled away, chemically removed, etc.) and a second resistant material 325 can then be deposited (e.g., spin cast, solution cast, thermally evaporated, electrostatically spun, etc.) and patterned (e.g., using photolithography, soft lithography, printing, etc.) on substrate 310 at 330. At least one opening (e.g., openings 327) may remain for allowing beam 105 to attach to substrate 310. Second resistant material 325 can be used to later provide a gap between beam 105 and first material surface 115. In some embodiments, without the gap between beam 105 and first material surface 115, beam 105 would be deposited on the substrate and beam 105 could not move. Second resistant material 325 can be a substantially similar material to first resistant material 305.

A third resistant material 345 can be deposited (e.g., spin cast, solution cast, thermally evaporated, electrostatically spun, etc.) and patterned (e.g., using photolithography, soft lithography, printing, etc.) to, for example, define the mold for beam 105, at 350. In some instances, first resistant material 305, second resistant material 325, and third resistant material 345 can include, for example, a photo resistant material (e.g., SU-8, AZ 5214E, AZ 4620, or any other light-sensitive material). In some instances, third resistant material 345 can be a substantially similar material to first resistant material 305 and second resistant material 325. At 355, a material layer 360 can be added on top of second resistant material 325 and contained by third resistant material 345. Material layer 360 can be any suitable material (e.g., metal, semiconductor, polymer, nickel metal, nickel alloy, etc.). It will be apparent that material layer 360 can become beam 105. For example, beam 105 can be produced by nickel electroplated onto second resistant material 325 and contained by third resistant material 345 using a nickel sulfamate electroplating bath. At 365, second resistant material 325 and third resistant material 344 can be removed (e.g., dissolving away in acetone in an ultrasonic bath, thermally degraded, peeled away, chemically removed, etc.). After 365, a gap 370 is produced where second resistant material 325 used to be before it was removed. At 375, hole 110 can then be produced, for example, by etching through material 310. It will be apparent that substrate 310 can become first material 115.

Referring to FIG. 3B, in some embodiments, prior to 350, a seed layer 340 can be added on top of second resistant layer 325. For example, at 335, seed layer 340 can be deposited (e.g., spin cast, solution cast, thermally evaporated, electrostatically spun, etc.) and patterned (e.g., using photolithography, soft lithography, printing, etc.) over second resistant layer 325. Seed layer 340 can be any suitable material capable of acting as an electroplating seed layer (e.g., gold layer, chromium/gold layer, etc.). In some instances, for example, the thickness of seed layer 340 can range from about 10-1000 nanometers.

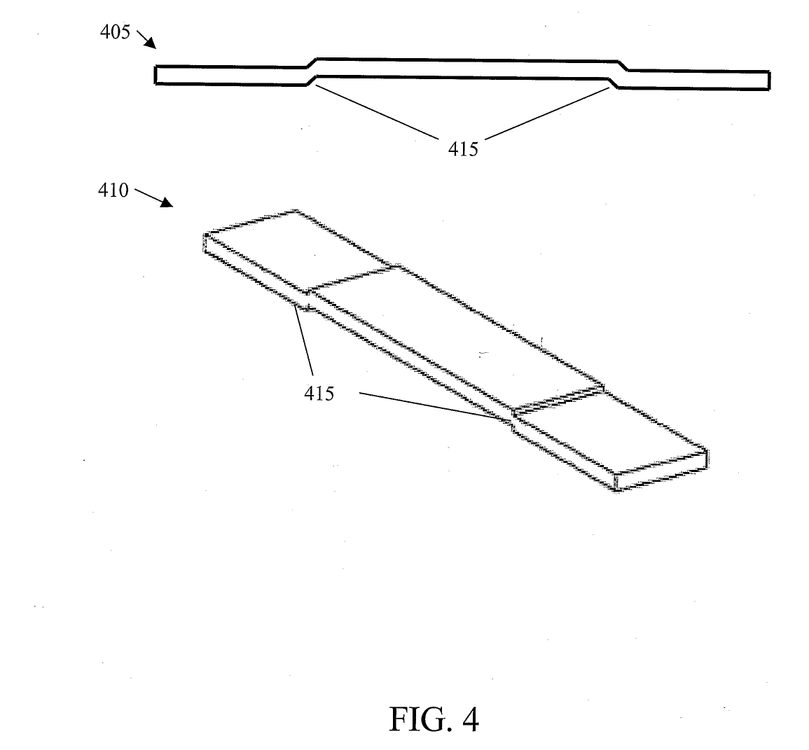

Referring to FIG. 4, in some embodiments, beam 105 can be constructed with an eccentricity 415 for at least encouraging buckling. As shown, side view 405 and orthogonal view 410 display eccentricity 415 in beam 105. The depth for eccentricity 415 can be about, for example, 0.1 to 5 microns. In some embodiments, eccentricity 415 can cause beam 105 to buckle in a desired direction. For example, eccentricity 415 can determine the buckling direction and amplify deflections associated with the buckling. In some embodiments, beam 105 does not include eccentricity 415. In some embodiments, eccentricity 415 is a “step” that creates an asymmetry. Asymmetries can be made in many other ways (e.g., thinning of beam 105, etc.) to determine buckling direction.

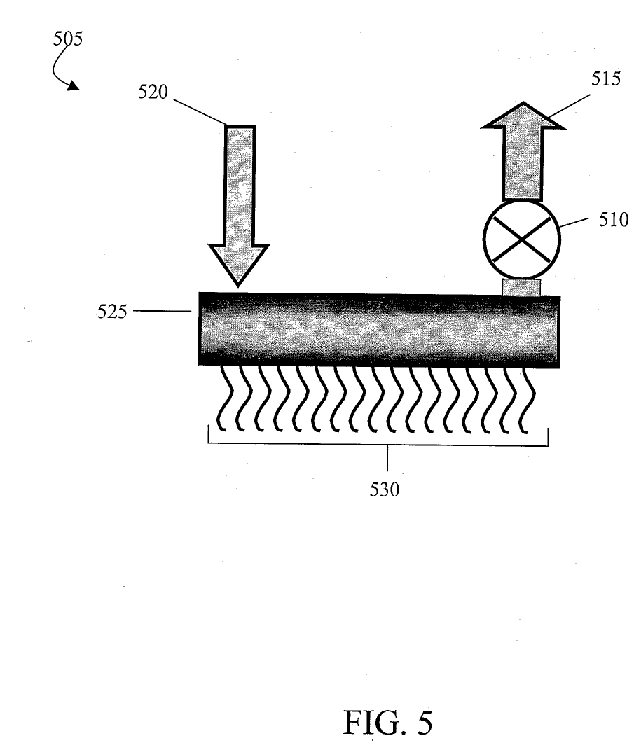

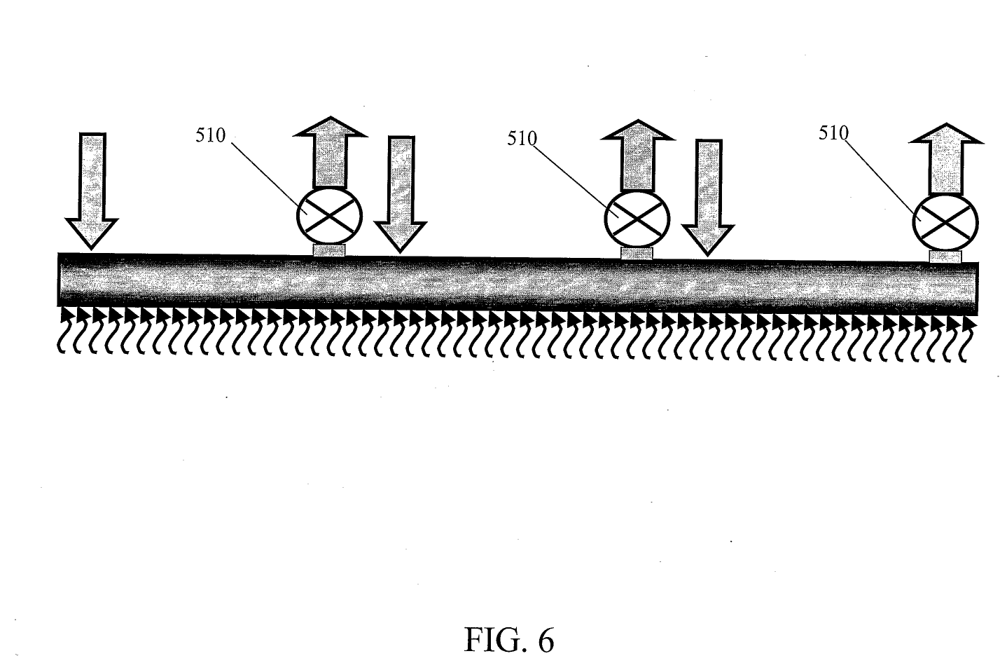

Referring to FIG. 5, in some embodiments, a thermally actuated micro-valve can control flow (e.g., coolant flow, water flow, steam flow, etc.) in a heat exchanger. For example, a heat exchanger 505 can include a thermally actuated micro-valve 510, an exit flow 515, an entry flow 520, and an exchanger 525. Thermally actuated micro-valve 510 can control exit flow 515 from exchanger 525. In use, for example, entry flow 520 (e.g., cold water) passes through exchanger 505 and a heat load 530 can be applied to the flow. When a sufficient temperature is reached, thermally actuated micro-valve 510 can open (e.g., when beam 105 buckles) and exit flow 515 (e.g., hot water) can leave the exchanger. Further, referring to FIG. 6, in some embodiments, an array of thermally actuated micro-valves 510 can be used to control an array of heat exchangers. That is, the fluid flow through one thermally actuated micro-valve can be minimal, however, the fluid flow through a large plurality of thermally actuated micro-valves can be substantially significant amount. A fluid can be a liquid or a gas.

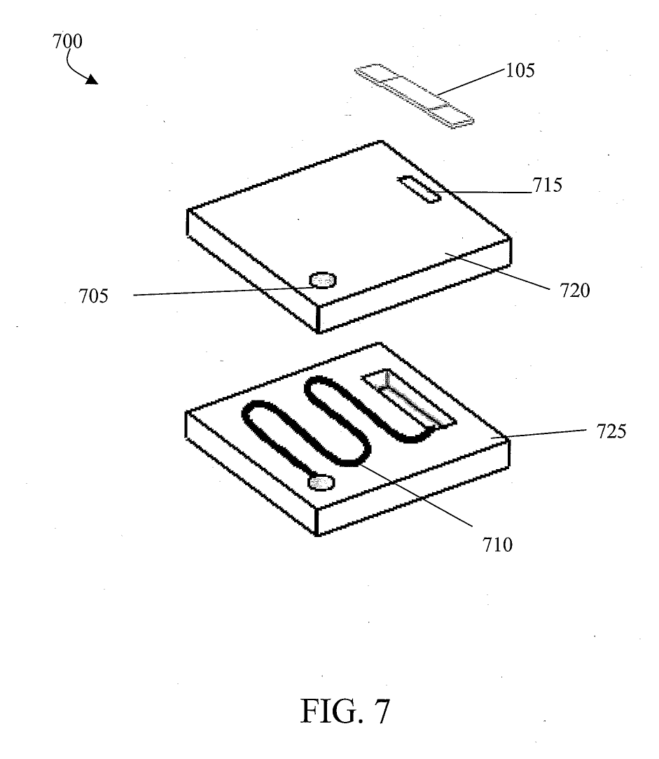

Referring to FIG. 7, in some embodiments, a thermally actuated micro-valve can be constructed into the housing of a heat exchanger. For example, a heat exchanger 700 can be constructed with an intake 705 in a top portion 720, an s-pattern cooling region 710 in a bottom portion 725, an output 715 in the top portion, and beam 105 at least partially covering output 715. In some instances, output 715 can function similarly to opening 110 for a thermally actuated micro-valve and the heat exchangers housing can function similarly to first material 115. Beam 105, at least partially covering output 715, can allow control over the output from the heat exchanger.

In some embodiments, a thermally actuated micro-valve can be used in photovoltaic cell, in aeronautical machines, and can be built directly electronics for cooling. For example, when the electronics are inactive they may not be dissipating heat and, thus, may be cold, and when the electronics are activated they may heat up and cause the micro-valve to open, allowing coolant to pass through. In some embodiments, many flat surfaces can function as first material 115 and an opening can be placed in that flat surface to produce opening 110. Similarly, a thermally actuated micro-valve can be built into various mechanical and electromechanical applications (e.g., gas turbine blade cooling, nuclear reactors, combustors, heat exchangers, rocket engines, hypersonic vehicles, space vehicles, etc.).

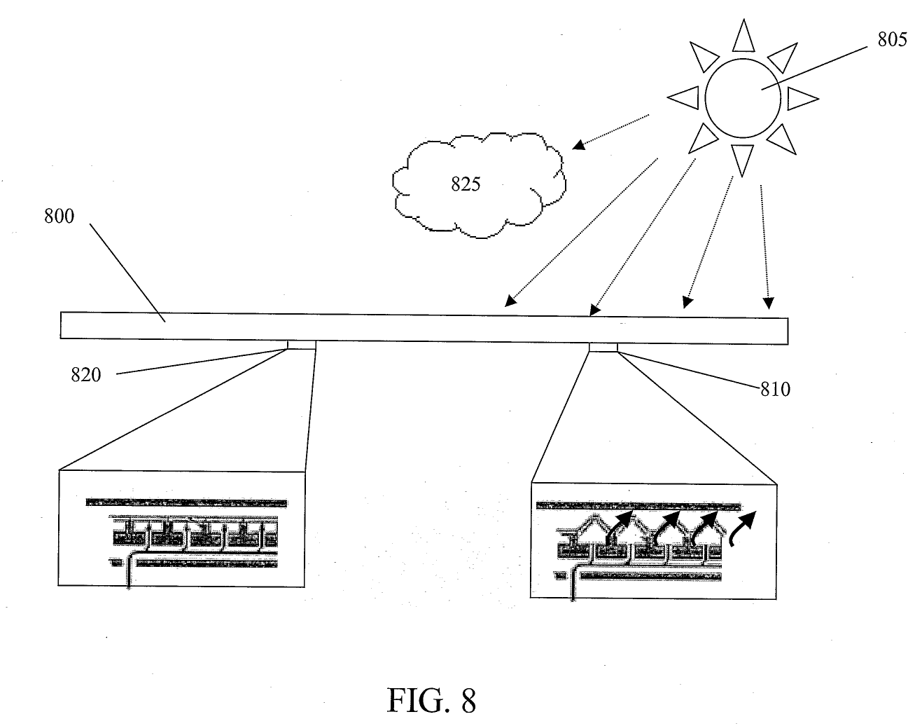

Referring to FIG. 8, thermally actuated micro-valves can be used to deliver coolants to a photovoltaic cell 800. In some instances, thermally actuated micro-valves can be located on the backside (e.g., the side facing away from a sun 805) of photovoltaic cells 800. As light heats up some photovoltaic cells (e.g., hot region 810 exposed to sun 805), thermally actuated micro-valves can open (e.g., beam 105 buckles), allowing coolant to flow through the valves to cool the cells. In regions that are not substantially hot (e.g., cool region 820 shaded by cloud 825), thermally actuated micro-valves can remain closed (e.g., beam 105 does not buckle) inhibiting the flow of coolant through the valves. This can be done to reduce the cost associated with cooling a photovoltaic cell. For example, the cost of cooling could be reduced by not running a constant stream of coolant, but rather only running a coolant stream when a specified temperature is reached. Coolant flow through thermally actuated micro-valves can be in parallel or in series.

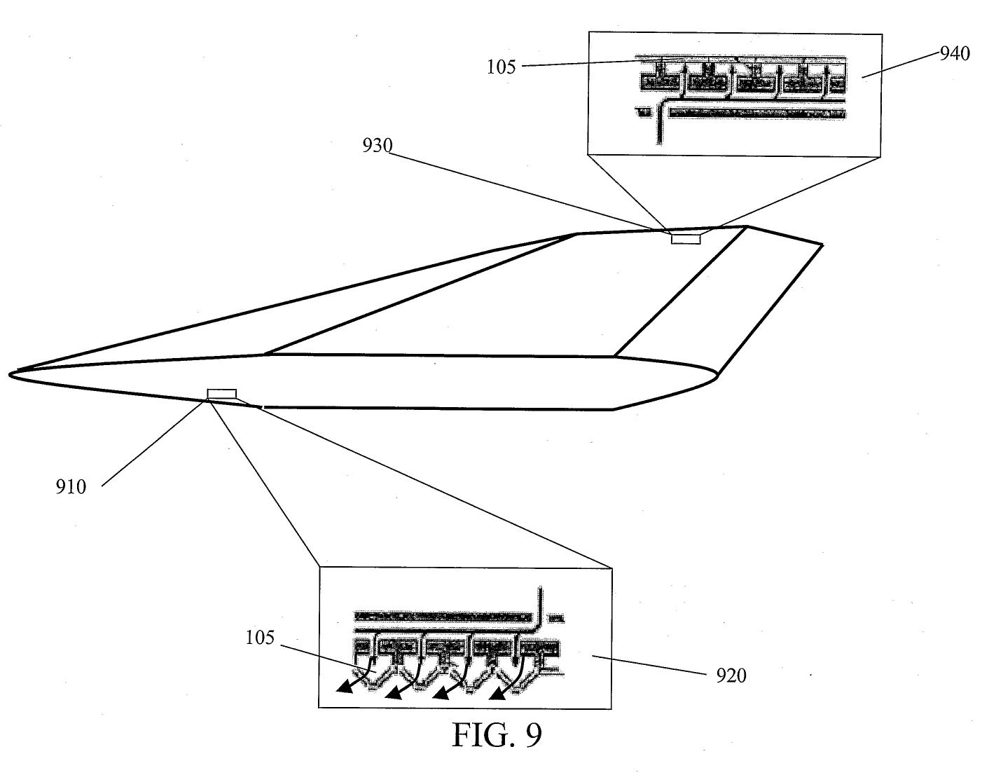

Referring to FIG. 9, in some embodiments, an array of thermally actuated micro-valves can be placed under the exposed surface of an aeronautical vehicle. For example, thermally actuated valves can be placed under the exposed surface of a wing of hypersonic jet. This can be done to allow a coolant to flow and limit heat damage due to, for example, frictional forces (e.g., hyper sonic flight, reentry into the earths atmosphere, etc.). For example, hot region 910 displays an array of thermally actuated micro-valves 920 open (e.g., beams 105 buckled) and allowing coolant to flow through, whereas cool region 930 displays an array of thermally actuated micro-valves 940 closed (e.g., beams 105 not buckled) and inhibiting coolant flow through. It will be apparent that only delivering coolant to regions requiring cooling can substantially increase the cooling efficiency for an aeronautical vehicle or any other object requiring cooling.

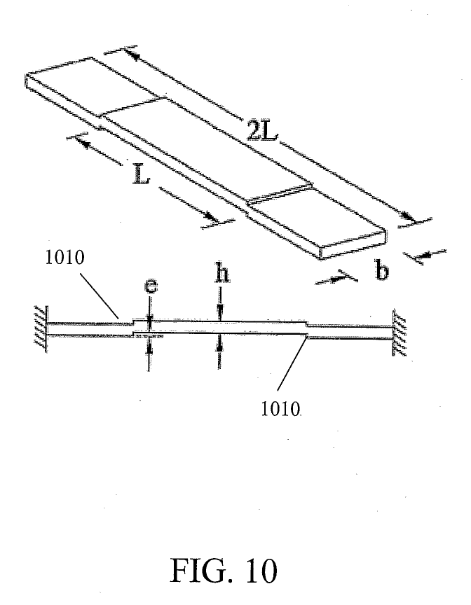

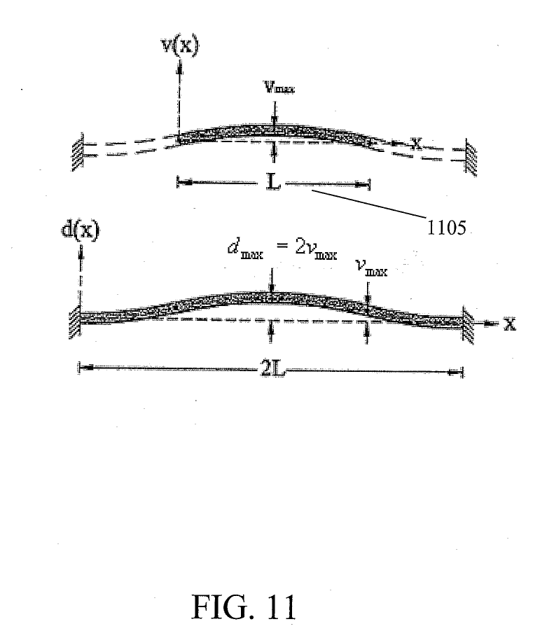

Referring to FIGS. 10-17, in some embodiments, mathematical and graphical relationship can be used in producing a thermally actuated micro-valve. Referring to FIGS. 10-11, in some embodiments, an elastic analysis of clamped-clamped beams (i.e., a beam that is clamped to surface at both ends of the beam) under thermal loading can be carried out with the assumption of small beam curvatures. Referring to FIG. 11, in some instances, for example, a symmetric clamped-clamped beam of length 2L buckling under a compressive force can be analyzed as a pinned-pinned beam (i.e., a beam that is free to rotate but not translate at both ends of the beam) of length L 1105 under the same loading. In some instances, the pinned ends can correspond to inflection points in the symmetric clamped-clamped beam exhibiting negligible internal moments.

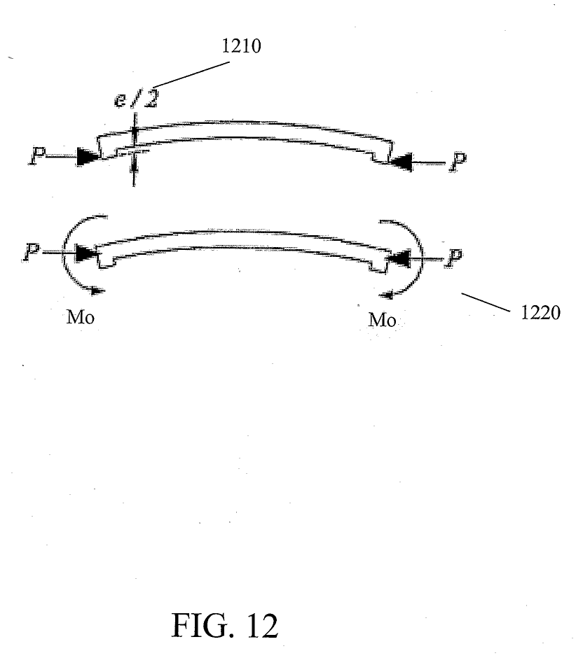

In some embodiments, the clamped eccentric beam, displayed in FIG. 10, can also be simplified as a pinned beam. In some instances, the inflection points 1010 of the beam can coincide with eccentricity locations. For example, referring to FIG. 12, the point of zero moment in the beam can be located at half the eccentric height (i.e., e/2) 1210. The resultant loading and deflection of the beam can therefore be symmetric about this point. In some embodiments, using this type of analysis, the elastic curve and the state of stress can be analyzed and in some instances used to produce thermally actuated micro-valves. For example, the pinned beam-column with a compressive load (e.g., P) applied at an eccentric distance of e/2 can be statically equivalent to an axially loaded beam with an additional moment (M₀=Pe/2) applied at the ends 1220.

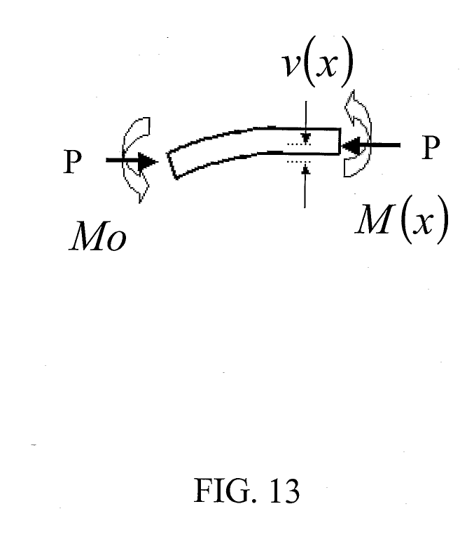

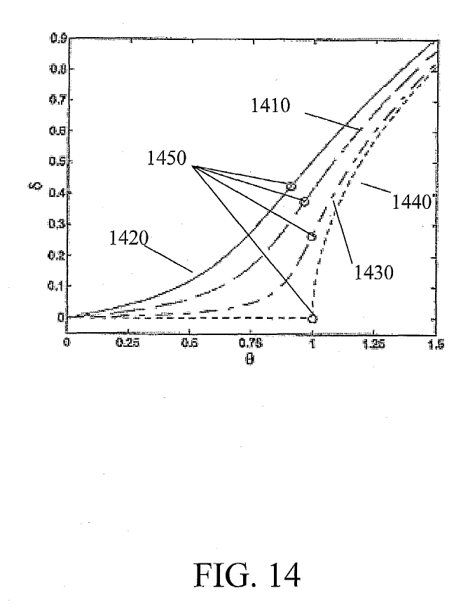

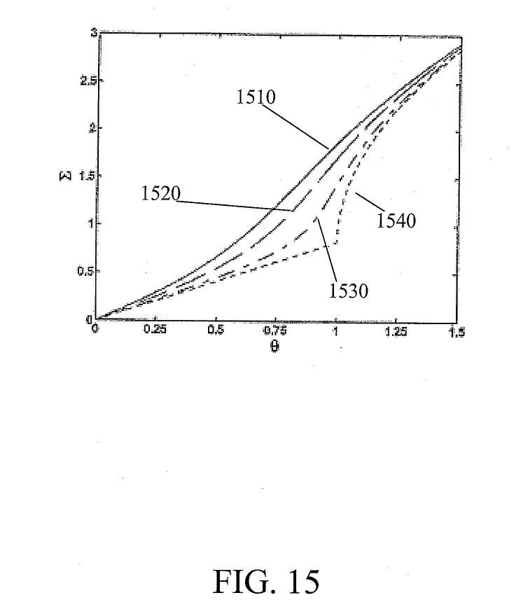

Referring to FIGS. 13-15, in some embodiments, the elastic curve for the beam can be determined mathematically and displayed graphically. In some instances, assuming shallow beam curvatures, by considering the moment induced by lateral deflection of the beam, the elastic curve for the beam can be displayed graphically (FIGS. 14-15). For example, graphs can be generated using equations 1-4, below, where v is the pinned-pinned deflection, I is the beam moment of inertia, E is the modulus of elasticity, M is the moment, P is the axial force, and e is the eccentricity. Equation 1 comes from the theory of elastic stability wherein the second derivative of deflection is proportional to the internal moment in the beam. Equation 2 is Equation 1 rearranged along with the boundary conditions associated with a pinned-pinned beam (e.g., the deflections at the endpoints is zero). Equation 2 is an ordinary differential equation with its boundary conditions. Equation 3 is the solution to the ordinary differential equation in Equation 2. Referring back to FIG. 11, because the central deflection of the associated pinned-pinned problem, d, is twice that of the central deflection of the pinned-pinned problem (i.e., v(x=L/2)), equation 4 can be found as shown below.

$$\begin{matrix}E I \frac{{d}^{2} v}{d {x}^{2}} = M ( x ) = - {M}_{0} - Pv = - P ( \frac{e}{2} + v ) & ( 1 ) \\ \frac{{d}^{2} v}{d {x}^{2}} + ( \frac{P}{E I} ) v = - \frac{Pe}{2 E I} & ( 2 A ) \\ v ( 0 ) = v ( L ) = 0 & ( 2 B ) \\ v ( x ) = \frac{e}{2} [ tan ( \frac{L}{2} \sqrt{\frac{P}{E I}} ) sin ( \sqrt{\frac{P}{E I}} x ) + cos ( \sqrt{\frac{P}{E I}} x ) - 1 ] & ( 3 ) \\ d = 2 v ( x = L / 2 ) = e [ sec ( \frac{L}{2} \sqrt{\frac{P}{E I}} ) - 1 ] & ( 4 )\end{matrix}$$

In some embodiments, the maximum stress in the beam can be calculated and used to produce a thermally actuated valve. In some embodiments, a buckling beam under compressive loading is subjected to both axial and bending stress. The maximum of which can be compressive and located at the midpoint on the lower surface of the beam. In some instances, the maximum stress can be written as the sum of two components using equation 5, where b refers to the beam width and h refers to the beam thickness. Using the magnitude of the internal moment at the midpoint, as given by equation 1, equation 6 can be found and can yield the maximum stress in the buckling beam as given by equation 7. In some instances, equations 4 and 7 can define the beam central deflection and maximum stress as a function of axial load. An additional relation can be needed to relate the axial force, P, to the average beam temperature rise, ΔT.

$$\begin{matrix}{σ}_{M} = {σ}_{A} + {σ}_{B} = \frac{P}{bh} + \frac{h}{2 I} \vert M ( x = L / 2 ) \vert & ( 5 ) \\ \vert M ( x = L / 2 ) \vert = P ( \frac{e}{2} + v ( x = L / 2 ) ) = ( \frac{Pe}{2} ) sec ( \frac{L}{2} \sqrt{\frac{P}{E I}} ) & ( 6 ) \\ {σ}_{M} = \frac{P}{bh} [ 1 + 3 ( e / h ) sec ( \frac{L}{2} \sqrt{\frac{P}{E I}} ) ] & ( 7 )\end{matrix}$$

In some embodiments, the stress-strain relationship can be determined mathematically and can be used in the production of a thermally actuated micro-valve. For example, equation 8 considers the stress-strain relationship of a heated beam restrained from expansion in the axial direction. In equation 8, α is the difference in the coefficient of thermal expansion between the beam and the substrate, ΔT is the average rise of the beam, σ_{A} is the axial stress, and ε′ is the strain related to beam elongation. Referring to equation 10, l can be defined as the deformed beam length. The assumption of shallow beam curvatures can be written as dv/dx<<1. The integrand in equation 10 can be simplified to equation 11 and the strain term in equation 8 can be rewritten as equation 12.

$$\begin{matrix}{σ}_{A} = \frac{P}{bh} = E [ αΔ T - {ɛ}^{′} ] & ( 8 ) \\ {ɛ}^{′} = \frac{l - L}{L} & ( 9 ) \\ l = {\int }_{0}^{L} \sqrt{1 + {( \frac{d v}{d x} )}^{2}} d x & ( 10 ) \\ \sqrt{1 + {( \frac{d v}{d x} )}^{2}} ≅ 1 + \frac{1}{2} {( \frac{d v}{d x} )}^{2} & ( 11 ) \\ {ɛ}^{′} ≅ \frac{1}{2 L} {\int }_{0}^{L} {( \frac{d v}{d x} )}^{2} d x & ( 12 )\end{matrix}$$

Using v(x) from equation 3, both the derivative and integral from equation 12 can be evaluated. Equation 13 can be found by dropping the approximate equality, combining equation 8 and equation 12, and rearranging terms. Equation 12, can define the relationship between the applied axial load and average temperature rise of the beam stress.

$$Δ T = \frac{P}{α Ebh} [ 1 + \frac{3}{4} {( e / h )}^{2} \{ \begin{matrix}\begin{matrix}\frac{tan ( \frac{L}{2} \sqrt{\frac{P}{E I}} ) cos ( 2 L \sqrt{\frac{P}{E I}} )}{L \sqrt{\frac{P}{E I}}} + \\ {tan}^{2} ( \frac{L}{2} \sqrt{\frac{P}{E I}} ) [ 1 + \frac{sin ( 2 L \sqrt{\frac{P}{E I}} )}{2 L \sqrt{\frac{P}{E I}}} ] +\end{matrix} \\ [ 1 - \frac{sin ( 2 L \sqrt{\frac{P}{E I}} )}{2 L \sqrt{\frac{P}{E I}}} ]\end{matrix} \} ] \qquad ( 13 )$$

In some embodiments, non-dimensional design curves and mathematical relationships can be used to produce of a thermally actuated micro-valve. In some embodiments, collectively equations 4, 7, and 13 can substantially describe the thermo-mechanical behavior of clamped-clamped eccentric beams. In some instances, several non-dimensional parameters can be defined to simplify these equations. Defining the critical load, Pcr, as the force at which a theoretically perfect beam (i.e., e=0) will buckle, equation 14 can be found. In equation 15, the critical temperature rise, ΔT_{cr}, can be defined by evaluating equation 8 at the critical load, noting, for example, that for a perfect beam prior to buckling there is no deflection and therefore no associated strain term, ε′. Using equation 14 and 15 and by examining equations 4, 7, and 13, non-dimensional forms of deflection δ, eccentricity ε, axial load η, maximum compressive stress Σ, and temperature rise θ can be defined by equations 16-20. Non-dimensional forms of equations 4, 7, and 13 can be obtained by rearranging and substituting in equations 16-20 yielding equations 21-23.

$$\begin{matrix}{P}_{cr} = \frac{{π}^{2} E I}{{L}^{2}} = \frac{{π}^{2} {Ebh}^{3}}{12 {L}^{2}} & ( 14 ) \\ Δ {T}_{cr} = \frac{{P}_{cr}}{α Ebh} = \frac{1}{12 α} {( \frac{π h}{L} )}^{2} & ( 15 ) \\ δ = d / h & ( 16 ) \\ ɛ = e / h & ( 17 ) \\ η = \frac{π}{2} \sqrt{\frac{P}{{P}_{cr}}} = \frac{L}{2} \sqrt{\frac{P}{E I}} & ( 18 ) \\ Σ = \frac{{σ}_{M}}{E} {( \frac{L}{h} )}^{2} & ( 19 ) \\ θ = \frac{Δ T}{Δ {T}_{cr}} = 12 α Δ {T ( \frac{L}{π h} )}^{2} & ( 20 ) \\ δ = ɛ [ sec η - 1 ] & ( 21 ) \\ Σ = {η}^{2} [ ( \frac{1}{3} ) + ɛ sec η ] & ( 22 ) \\ θ = {( \frac{2 η}{π} )}^{2} [ 1 + \frac{3}{4} {ɛ}^{2} \{ \frac{tan η cos 4 η}{2 η} + {tan}^{2} η ( 1 + \frac{sin 4 η}{4 η} ) + ( 1 - \frac{sin 4 η}{4 η} ) \} ] & ( 23 )\end{matrix}$$

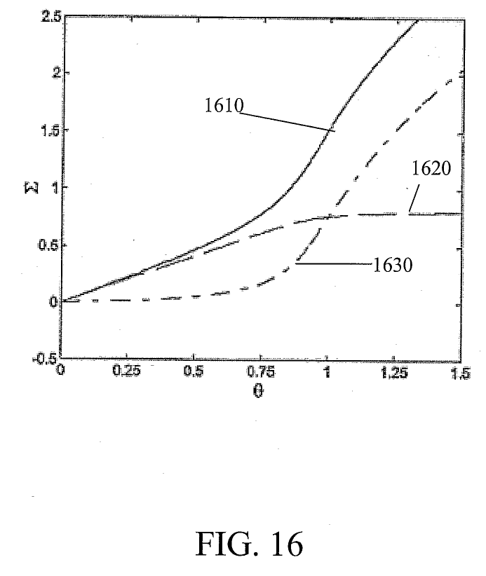

In some embodiments, non-dimensional equations 14-23 can be solved numerically using software (e.g., MATLAB available from The MathWorks, Inc., 3 Apple Hill Drive, Natick, Mass.) to eliminate the non-dimensional axial load η. Curves for central beam deflection δ, maximum compressive stress Σ, and its corresponding stress components are shown in FIGS. 14-15 respectively, as a function of temperature rise θ. Non-dimensional design curves for deflection (e.g., equation 16) as a function of temperature rise (e.g., equation 20) for various eccentricities (e.g., equation 17) is displayed in FIG. 14. Referring to FIG. 14, four eccentricities are plotted (i.e., ε=0 1410, ε=0.0125 1420, ε=0.05 1430, and ε=0.1 1440). Non-dimensional design curves for stress (e.g., equation 19) as a function of temperate rise (e.g., equation 20) for various eccentricities (e.g., equation 17) is displayed in FIG. 15. Referring to FIG. 15, four eccentricities are plotted (i.e., ε=0 1510, ε=0.0125 1520, ε=0.05 1530, and ε=0.1 1540). Referring to FIG. 16, in some embodiments a single eccentric value can be plotted to show the non-dimensional stress components. For example, the non-dimensional stress components for a beam with an eccentricity (e.g., ε=0.01) can be plotted to show total compressive stress plot 1610, axial stress plot 1620, and bending stress plot 1630.

In some embodiments, at low temperature rise (e.g., θ<<1) the beam behavior can be substantially controlled by axial compression and the beam deflection and stress can increase linearly with θ. In some instances, at high temperatures (e.g., θ>1), bending can begin to lead to increased deflections and therefore increased strain. At high temperatures, the strain term can limit the beam to finite deflections. At intermediate temperatures (e.g., 0.5<θ<1), the shape of the deflection and stress curves can be more sensitive to eccentricities, ε, and can exhibit very nonlinear behavior, for example, as seen in FIGS. 14 and 15.

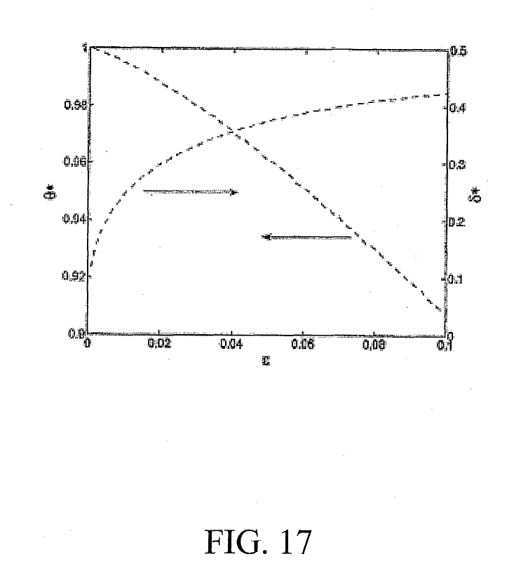

In some embodiments, the curves of deflection as a function of temperature rise shown in FIG. 14 can pass through an inflection point denoted as circles 1450. This can be the point of maximum slope and the boundary between positive and negative concavity of the temperature induction deflection. This can make the inflection point a key design parameter for implementing buckling beams into thermally actuated devices. For example, the location of this point at various eccentricities can be solved numerically using MATLAB. For example, first, let δ* and θ* define, respectively, the non-dimensional deflection and temperature rise of the beam and the inflection point. Referring to FIG. 17, in some embodiments, using this notation, the location of the inflection point can be solved and plotted as a function of eccentricity.

Referring to FIGS. 14 and 16, for a perfectly symmetric beam (i.e., ε=0) there can be zero deflection (i.e., δ=0) up until buckling occurs at the critical temperature (i.e., θ=1). The inflection point can therefore be at (δ*, θ*)=(0,1). For imperfect beams, ε≠0 continuous nonlinear deflections can be predicted and the point of maximum slope can vary as shown in FIG. 17.

In some embodiments, referring to FIGS. 14-16, succinct non-dimensional design curves for the implementation of thermally actuated buckled beams in a system are displayed. These curves, along with the preceding analysis, capture the complex and highly nonlinear behavior exhibited in thermally buckled beams. The beam shape, central deflection and state of stress can all be modeled as they vary with temperature and eccentricity.

In some embodiments, the valve mechanism shown in FIG. 2 can consist of a thermally buckling beam that can increase the thin air gap between itself and the substrate. For small deflections relative to the beam width, the flow through this thin air gap can be modeled as flow through two infinite parallel plates. The valve mass flow rate can vary as the cube of the contoured gap, d (x)³ dx, as given by equation 24, where v is the kinematic viscosity and w is the parallel plate flow distance underneath the beam. Using equation 24 along with a thermal buckling analysis, equations 25-27 can be found, where η is the non-dimensional axial force, e is the designed eccentricity, α is the difference in coefficient of thermal expansion between the beam and the substrate, and ΔT is the temperature rise above the zero stress state. In some instances, the half-length, thickness and moment of inertia of the beam are L, h, and I. Equation 25 indicates the mass flow rate per unit of driving pressure as a function of axial load, while equation 26 gives the beam temperature rise required to generate non-dimensional axial load, η. As the axial force, P, approaches the critical buckling load, η approaches π/2, and the mass flow rate per unit pressure drop substantially increases due to the secant term, leading to the desired non-linear valve response.

$$\begin{matrix}\dot{m} = \frac{Δ P}{6 wv} {\int }_{a}^{b} d {( x )}^{3} d x & ( 24 ) \\ \frac{\dot{m}}{Δ P} = [ \frac{L}{wv} ] ( \frac{15 π + 44}{288 π} ) {{e}^{3} ( see η - 1 )}^{3} & ( 25 ) \\ Δ T = \frac{1}{α} {( \frac{h}{L} )}^{2} [ \frac{{η}^{2}}{3} + {( \frac{e π}{4 h} )}^{2} {( see η - 1 )}^{2} ] & ( 26 ) \\ η = \frac{L}{2} \sqrt{\frac{P}{E I}} & ( 27 )\end{matrix}$$

In some embodiments, equations 25-26 can be nondimensionalized to yield equations 28-29 where φ is the nondimensional mass flow rate per unit pressure drop given by equation 30 and θ is the nondimensional temperature rise above zero stress state given by Equation 20.

$$\begin{matrix}φ = {{ɛ}^{3} ( sec η - 1 )}^{3} & ( 28 ) \\ θ = \frac{4}{{π}^{2}} {η}^{2} + \frac{3}{4} {{ɛ}^{2} ( sec η - 1 )}^{2} & ( 29 ) \\ φ = ( \frac{\dot{m}}{Δ P} ) [ \frac{wv}{{Lh}^{3}} ] ( \frac{288 π}{15 π + 44} ) & ( 30 )\end{matrix}$$

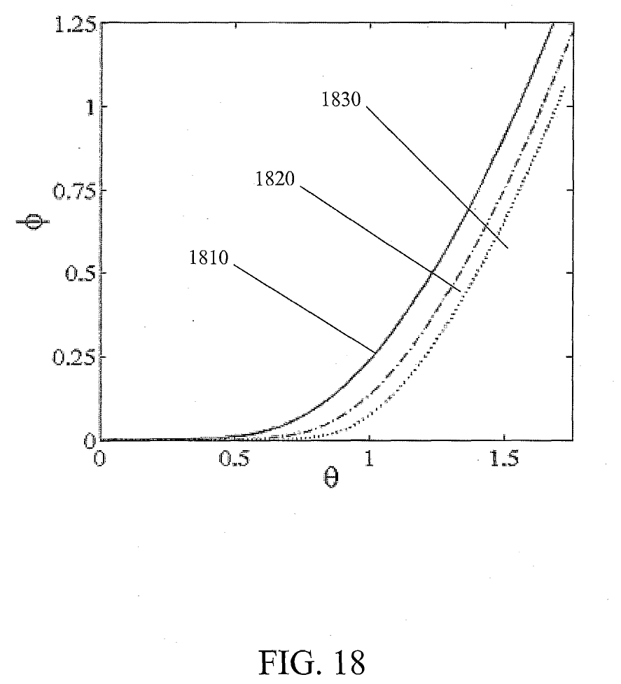

Referring to FIG. 18, in some embodiments, equation 28 can be plotted relative to equation 29 for various eccentricity ratios ε (e.g., ε=0.20 1810, ε=0.10 1820, ε=0.05 1830). FIG. 18 demonstrates, in nondimensional form, the mass flow rate per unit pressure drop through the valve as a function of the valve temperature rise over zero stress state for several eccentricity ratios. In some embodiments, the mass flow rate per unit pressure drop through the valve as a function of the valve temperature rise over zero stress state for several eccentricity ratios demonstrated nondimensionally can be used to design thermally actuated micro-valves (e.g., thermally actuated micro-valves used in micro-cooling applications).

Other embodiments, extensions, and modifications of the ideas presented above are comprehended and are within the reach of one versed in the art upon reviewing the present disclosure. Accordingly, the scope of the present invention in its various aspects is not to be limited by the examples presented above. The individual aspects of the present invention, and the entirety of the invention are to be regarded so as to allow for such design modifications and future developments within the scope of the present disclosure. Moreover, various features of the disclosed embodiments can be used in various combinations suitable to different applications. The present invention is limited only by the claims that follow.

What is claimed is:

1. A thermally actuated valve, comprising:
a first material defining at least one opening; and
a beam attached to the first material so as to at least partially cover the at least one opening,
wherein the first material and the beam comprise different thermal expansion properties, such that, when a temperature is applied to at least one of the first material and the beam, the beam buckles so as to at least partially uncover the at least one opening.

2. The thermally actuated valve of claim 1, wherein, when the beam buckles, a fluid can pass through the at least one opening.

3. The thermally actuated valve of claim 1, wherein the beam is in a contracted state when attached to the first material.

4. The thermally actuated valve of claim 1, wherein the beam buckles so that the mass flow rate through the valve increases nonlinearly once a given temperature is reached.

5. The thermally actuated valve of claim 1, wherein the beam comprises all eccentricity.

6. An array of valves, comprising:
a first material defining at least two openings;
a first beam attached to the first material so as to at least partially cover one of the at least two openings; and
a second beam attached to the first material so as to at least partially cover another of the at least two openings,
wherein the first material and each of the first beam and the second beam comprise different thermal expansion properties, such that, when a temperature is applied to at least one of the first material and the first beam, the first beam buckles so as to at least partially uncover the one of the at least two openings.

7. A photovoltaic cell, comprising:
a first material defining at least one opening; and
a beam attached to the first material so as to at least partially cover the at least one opening,
wherein the first material and the beam comprise different thermal expansion properties, such that, when a temperature is applied to at least one of the first material and the beam, the beam buckles so as to at least partially uncover the at least one opening.

8. A method for making a thermally actuated valve, comprising:
producing a first material defining at least one opening;
producing a beam having different thermal expansion properties from the first material on the first material so that the beam at least partially covers the at least one opening,
wherein when a temperature change is applied to at least one of the first material and the beam, the beam buckles at least partially uncovering the at least one opening.

9. The method of claim 8, wherein producing the beam comprises:
at least partially depositing a first resistant material on at least a portion of the first material;
at least partially removing at least part of the first material;
at least partially removing at least part of the first resistant material;
at least partially depositing at least one of a second resistant material and a third resistant material;
at least partially depositing a beam material; and
at least partially removing at least one of the first resisting material, the second resisting material and the third resistant material and releasing the beam material from the first material.

10. The method of claim 9, wherein depositing comprises using at least one of spin casting, solution casting, thermally evaporating, and electrostatic spinning.

11. The method of claim 9, further comprising patterning the first resistant material using at least one of photolithography, soft lithography, and printing.

12. The method of claim 9, further comprising removing at least part of first material using etching.

13. The method of claim 9, further comprising removing at least one of the first resistant material, second resistant material, and third resistant material by at least one of thermal evaporation, peeling away, and chemically removing.

14. The method of claim 9, wherein at least one of the first resistant material, second resistant material, and third resistant material comprises a photo resistant material.

15. The method of claim 9, wherein the beam material comprises electroplated nickel.

16. The method of claim 9, further comprising at least partially depositing a seed layer over the second resistant material.

18. The method of claim 8, further comprising producing the beam to buckle in at least one direction.

19. The method of claim 8, further comprising forming that at least one opening to pass liquid.

20. The method of claim 8, further comprising contracting the beam when attaching the beam to the first material.

21. The method of claim 8, further comprising producing the beam with an eccentricity.
